(19) United States
(12) Patent Application Publication
(10) Pub. No.: US 2018/0107082 A1
(43) Pub. Date: Apr. 19, 2018

(54) FLEXIBLE BOARD FOR COMPONENT MOUNTING, AND DISPLAY DEVICE

(71) Applicant: SHARP KABUSHIKI KAISHA, Sakai City, Osaka (JP)

(72) Inventors: TAKASHI SASAKI, Sakai City (JP); KOHJI NAGASAKA, Sakai City (JP); KAZUMASA HATA, Sakai City (JP)

(21) Appl. No.: 15/562,851

(22) PCT Filed: Mar. 25, 2016
(86) PCT No.: PCT/JP2016/059619

§ 371 Date: Sep. 28, 2017

(30) Foreign Application Priority Data
Apr. 1, 2015 (JP) 2015-075330

(51) Int. Cl. G02F 1/1362; H05K 1/02; H05K 1/18; G09G 3/36; G02F 1/1333

(52) U.S. Cl. CPC G02F 1/136286; H05K 1/028; H05K 1/18; G09G 2380/02; G09G 3/3688; G02F 1/133305; G09G 2300/0413; G09G 3/3677

(57) ABSTRACT

Provided is a component-mounting flexible board allowing mounted driver circuits to share the same display panel or circuit board regardless of the number of driver circuits.

Of two source drivers 31 and 32 mounted in an SOF package 30, the source driver 31 has output wiring patterns respectively pressure-bonded to connection terminals S₁ to S₉₆₀ included in a first connection terminal group 11 of a liquid crystal panel 10. The source driver 32 has output wiring patterns respectively pressure-bonded to connection terminals S₁ to S₉₆₀ included in a second connection terminal group 12 of the liquid crystal panel 10. Dummy wiring patterns 36 are pressure-bonded to two dummy connection terminals 18 formed in a spared space between the first connection terminal group 11 and the second connection terminal group 12 of the liquid crystal panel 10.

### TECHNICAL FIELD

The present invention relates to component-mounting flexible boards and display devices, particularly to a component-mounting flexible board for packaging components required for driving a display device such as a liquid crystal display device, as well as a display device.

### BACKGROUND ART

Currently, 4K and 8K televisions, which offer higher resolution than does a full high-definition television, are being developed actively. Source drivers required for driving an ultra-high-definition liquid crystal panel as used in such a television are mounted in SOF (system on film) packages disposed on the liquid crystal panel, and apply analog signal voltages, which are generated on the basis of an externally inputted image signal, to source signal lines. As a result, the analog signal voltages are written to pixel forming portions of the liquid crystal panel, with the result that an ultra-high-definition image is displayed.

However, when compared to conventional liquid crystal panels, the ultra-high-definition liquid crystal panel has more source signal lines densely formed in a narrow area. In the case where such a liquid crystal panel has disposed thereon source drivers with the same outputs as conventional source drivers, the source drivers are required to be arranged closely, and therefore, the SOF package size is required to be reduced. As a result, there is a problem where the SOF package does not have sufficient space spared for forming wiring patterns for supplying input terminals of the source driver with image data and control signals, which are provided by a timing controller, and applying analog signal voltages, which are provided from output terminals, to data signal lines of the liquid crystal panel.

Accordingly, each adjacent pair of SOF packages are replaced by a single SOF package in which two source drivers are disposed at a predetermined interval so as to be parallel to each other along the longitudinal direction but displaced from each other in the longitudinal direction. This renders it possible to ensure spaces spared for forming the wiring patterns not only between the right and left short sides of the source drivers and the edges of the SOF package but also between the two source drivers. Patent Document 1 discloses mounting a plurality of integrated circuits in a single SOF package as described above so as to be displaced from each other in the longitudinal direction.

### CITATION LIST

### Patent Document

Patent Document 1: Japanese Laid-Open Patent Publication No. 2002-141377

### SUMMARY OF THE INVENTION

### Problems to be Solved by the Invention

If source driver production technology further advances, thereby making it possible to achieve further miniaturization, the source driver can be rendered more compact, with the result that, even when one source driver is mounted in each SOF package, it is possible to ensure a space spared for forming wiring patterns. However, if there is any change in output wiring patterns of the SOF package, it is also necessary to change the arrangement of connection terminals of the liquid crystal panel to which the output wiring patterns of the SOF package are pressure-bonded. Accordingly, the liquid crystal panel that has been used up until now can no longer be used, and it is necessary to design a new liquid crystal panel. Likewise, it is also necessary to design a new source substrate to which input wiring patterns of the SOF package are pressure-bonded. Consequently, the production cost of the liquid crystal display device increases.

Therefore, an objective is to provide a component-mounting flexible board allowing mounted driver circuits to share the same display panel or circuit board regardless of the number of driver circuits, as well as a display device using the same.

### Means for Solving the Problems

A first aspect of the present invention is directed to a component-mounting flexible board for electrically connecting a display panel of a display device and a circuit board for supplying either image data or a control signal, or both, for driving the display panel, the component-mounting flexible board including:

a flexible film substrate;

a plurality of driver circuits configured to drive the display panel on the basis of either the image data or the control signal, or both, the driver circuits being mounted on the film substrate;

a plurality of input wiring patterns formed on the film substrate for each of the driver circuits so as to electrically connect input terminals of the driver circuit to the circuit board; and

a plurality of output wiring patterns formed on the film substrate for each of the driver circuits so as to electrically connect output terminals of the driver circuit to the display panel, wherein,

the input wiring patterns constitute an input wiring pattern group for each of the driver circuits,

the output wiring patterns constitute an output wiring pattern group for each of the driver circuits, and

a first looseness prevention portion is formed either in a spared space between the input wiring pattern groups or a spared space between the output wiring pattern groups, or both.

A second aspect of the present invention provides the component-mounting flexible board according to claim 1, wherein the first looseness prevention portion consists of one or more dummy wiring patterns.

A third aspect of the present invention provides the component-mounting flexible board according to claim 1, wherein the first looseness prevention portion is a cut provided in the film substrate.

A fourth aspect of the present invention provides the component-mounting flexible board according to any of claims 1 through 3, wherein the component-mounting flexible board is an SOF package.

A fifth aspect of the present invention provides the component-mounting flexible board according to any of claims 1 through 3, wherein the component-mounting flexible board is a TCP.

A sixth aspect of the present invention provides the component-mounting flexible board according to claim 1, wherein both the input wiring pattern groups and the output wiring pattern groups are arranged such that the first looseness prevention portion formed in the spared space is interposed therebetween.

A seventh aspect of the present invention provides the component-mounting flexible board according to claim 1, wherein the driver circuit is a data signal line driver circuit configured to generate an analog signal voltage on the basis of the image data and apply the analog signal voltage to a data signal line formed on the display panel.

An eighth aspect of the present invention is directed to a display device, the display device including:

a display panel configured to display an image;

a component-mounting flexible board of claim 1 having mounted thereon a plurality of driver circuits configured to drive the display panel; and

a circuit board configured to supply image data and a control signal to the driver circuits, wherein,

the display panel includes for each of the driver circuits an output connection terminal group consisting of a plurality of connection terminals for connecting output wiring patterns of the component-mounting flexible board to the driver circuit,

the circuit board includes for each of the driver circuits an input connection terminal group consisting of a plurality of connection terminals for connecting input wiring patterns of the component-mounting flexible board to the driver circuit, and

either the output connection terminal groups of the display panel or the input connection terminal groups of the circuit board, or both, are arranged such that a second looseness prevention portion is disposed at a position corresponding to a first looseness prevention portion formed in or on the component-mounting flexible board.

A ninth aspect of the present invention provides the display device according to claim 8, wherein,

the first looseness prevention portion formed in or on the component-mounting flexible board consists of one or more dummy wiring patterns, and

the second looseness prevention portion formed on the display panel or the circuit board consists of one or more dummy connection terminals connectable to the dummy wiring pattern.

A tenth aspect of the present invention provides the display device according to claim 8, wherein,

the first looseness prevention portion formed in or on the component-mounting flexible board is a cut,

the second looseness prevention portion formed on the display panel or the circuit board is a spared space, and

the component-mounting flexible board is pressure-bonded to the display panel or the circuit board such that the cut overlaps neither the display panel nor the circuit board.

### Effect of the Invention

In the first aspect of the present invention, the component-mounting flexible board with the driver circuits mounted thereon has formed thereon for each driver circuit the input wiring pattern groups, each consisting of a plurality of input wiring patterns, and the output wiring pattern groups, each consisting of a plurality of output wiring patterns. Either the input wiring pattern groups or the output wiring pattern groups, or both, are disposed so as to sandwich the first looseness prevention portion formed in a spared space. Thus, even when a component-mounting flexible board with only one driver circuit mounted thereon is used in place of the component-mounting flexible board according to the first aspect of the present invention, the display panel and the circuit board that have been used up until now can continue to be used. As a result, display device production cost can be reduced. Moreover, the first looseness prevention portion is provided, with the result that the component-mounting flexible board can be precluded from loosening from the display panel or the circuit board, and therefore, it is possible to prevent the occurrence of connection defects at the portions where the component-mounting flexible board is pressure-bonded to the display panel or the circuit board.

In the second aspect of the present invention, the first looseness prevention portion formed in the spared space on the component-mounting flexible board consists of one or more dummy wiring patterns. Accordingly, when the component-mounting flexible board is pressure-bonded to the display panel or the circuit board, the dummy wiring pattern is pressure-bonded to a dummy connection terminal formed in a spared space on the display panel or the circuit board, with the result that the component-mounting flexible board does not loosen from the display panel or the circuit board at the position of the spared space. Thus, it is possible to prevent the occurrence of connection defects at the portions where the component-mounting flexible board is pressure-bonded to the display panel or the circuit board.

In the third aspect of the present invention, the first looseness prevention portion formed in the spare space on the component-mounting flexible board is a cut. As a result, when the component-mounting flexible board is pressure-bonded to the display panel or the circuit board, the spared space on the component-mounting flexible board does not overlap the spared space on the display panel or the circuit board, and therefore, the component-mounting flexible board does not loosen from the display panel or the circuit board at the position of the spared space. Thus, it is possible to prevent the occurrence of connection defects at the portions where the component-mounting flexible board is pressure-bonded to the display panel or the circuit board.

In accordance with the fourth aspect of the present invention, as the component-mounting flexible board, an SOF package can be used. The SOF package is suitable for forming fine wiring patterns, and therefore, if the SOF package is used as the component-mounting flexible board, a driver circuit with a number of terminals can be mounted.

In accordance with the fifth aspect of the present invention, as the component-mounting flexible board, a TCP can be used.

In the sixth aspect of the present invention, the first looseness prevention portion is disposed in each of the spared spaces between the input wiring pattern groups and between the output wiring pattern groups. Thus, the component-mounting flexible board is precluded from loosening from the display panel and the circuit board, thereby preventing the occurrence of connection defects at the pressure-bonded portions. Moreover, also in the case where a component-mounting flexible board with one driver circuit mounted thereon is used in place of the aforementioned component-mounting flexible board, both the display panel and the circuit board that have been used up until now can continue to be used.

In the seventh aspect of the present invention, the driver circuit mounted on the component-mounting flexible board is a data signal line driver circuit configured to apply analog signal voltages, which are generated on the basis of image data, to data signal lines formed on the display panel. By pressure-bonding such a component-mounting flexible board to the display panel and the circuit board, it is rendered possible to display an image on an ultra-high-definition display panel.

In the eighth aspect of the present invention, the first looseness prevention portion of the component-mounting flexible board is formed such that, when the component-mounting flexible board is pressure-bonded to either the display panel or the circuit board, or both, the first looseness prevention portion is provided so as to be positioned corresponding to a second looseness prevention portion provided on either the display panel or the circuit board, or both. Thus, the component-mounting flexible board with a plurality of driver circuits mounted thereon is precluded from loosening from the display panel or the circuit board. Moreover, even when a component-mounting flexible board with only one driver circuit, rather than a plurality of driver circuits, mounted thereon is pressure-bonded to the display panel or the circuit board, the display panel or the circuit board that has been used up until now can continue to be used, and therefore, display device production cost can be reduced. Moreover, the first and second looseness prevention portions are provided, with the result that the component-mounting flexible board can be precluded from loosening from the display panel or the circuit board, and therefore, it is possible to prevent the occurrence of connection defects at the portions where the component-mounting flexible board is pressure-bonded to the display panel or the circuit board.

In the ninth aspect of the present invention, when the component-mounting flexible board is pressure-bonded to the display panel or the circuit board, the dummy wiring pattern formed on the component-mounting flexible board as the first looseness prevention portion is pressure-bonded to the dummy wiring pattern formed in a spared space on the display panel or the circuit board as the second looseness prevention portion. As a result, the component-mounting flexible board does not loosen from the display panel or the circuit board at the position of the spared space. Thus, it is possible to prevent the occurrence of connection defects at the portions where the component-mounting flexible board is pressure-bonded to the display panel or the circuit board.

In the tenth aspect of the present invention, when the component-mounting flexible board is pressure-bonded to the display panel or the circuit board, the component-mounting flexible board does not overlap a spared space, which serves as a second looseness prevention portion, on the display panel or the circuit board because of the first looseness prevention portion provided as a cut in the component-mounting flexible board. Therefore, the component-mounting flexible board does not loosen from the display panel or the circuit board at the position of the spared space. Thus, it is possible to prevent the occurrence of connection defects at the portions where the component-mounting flexible board is pressure-bonded to the display panel or the circuit board.

### BRIEF DESCRIPTION OF THE DRAWINGS

FIG. 1 is a block diagram illustrating the configuration of a liquid crystal display device according to a first embodiment of the present invention.

FIG. 2 is a diagram illustrating the arrangement of data signal lines and scanning signal lines formed on a liquid crystal panel included in the liquid crystal display device according to the first embodiment.

FIG. 3 is a diagram showing the arrangement of input terminals and output terminals of a source driver included in the liquid crystal display device according to the first embodiment.

FIG. 4 is a plan view of an SOF package included in the liquid crystal display device according to the first embodiment where two source drivers are mounted.

FIG. 5 is a diagram illustrating the layout of input wiring patterns and output wiring patterns for the source drivers of the SOF package shown in FIG. 4.

FIG. 6 is a diagram illustrating in cross section the SOF package shown in FIG. 4 with the source driver mounted therein.

FIG. 7 is a diagram showing a part of the arrangement of connection terminals which are formed on the liquid crystal panel included in the liquid crystal display device according to the first embodiment and to which the SOF package is to be pressure-bonded.

FIG. 8 is a diagram showing a part of the arrangement of connection terminals which are formed on a source board included in the liquid crystal display device according to the first embodiment and to which the SOF package is to be pressure-bonded.

FIG. 9 is a diagram illustrating the state where the SOF package included in the liquid crystal display device according to the first embodiment is pressure-bonded to the liquid crystal panel and the source board.

FIG. 10 is a diagram illustrating the connection of the SOF package included in the liquid crystal display device according to the first embodiment to the connection terminals of the liquid crystal panel.

FIG. 11 is a diagram illustrating an SOF package included in the liquid crystal display device according to the first embodiment where a miniaturized source driver is mounted.

FIG. 12 is a diagram illustrating the liquid crystal display device according to the first embodiment where SOF packages, as shown in FIG. 11, are pressure-bonded to the liquid crystal panel and the source board.

FIG. 13 is a diagram illustrating a liquid crystal display device according to a variant of the first embodiment where only the liquid crystal panel is provided with dummy connection terminals, and the SOF package is pressure-bonded to the liquid crystal panel and the source board.

FIG. 14 is a diagram illustrating the liquid crystal display device according to the variant of the first embodiment where SOF packages, each having one source driver mounted therein, are pressure-bonded to the liquid crystal panel and the source board.

FIG. 15 is a plan view of an SOF package used in a liquid crystal display device according to a second embodiment of the present invention where two source drivers are mounted.

FIG. 16 is a diagram illustrating the liquid crystal display device according to the second embodiment where the SOF package is pressure-bonded to the liquid crystal panel and the source board.

FIG. 17 is a diagram illustrating in cross section a TCP with a source driver provided therein.

FIG. 18 is a plan view illustrating a SOF package 230 with three source drivers 31 to 33 mounted therein.

### MODES FOR CARRYING OUT THE INVENTION

### 1. First Embodiment

<1.1 Configuration of the Liquid Crystal Display Device>

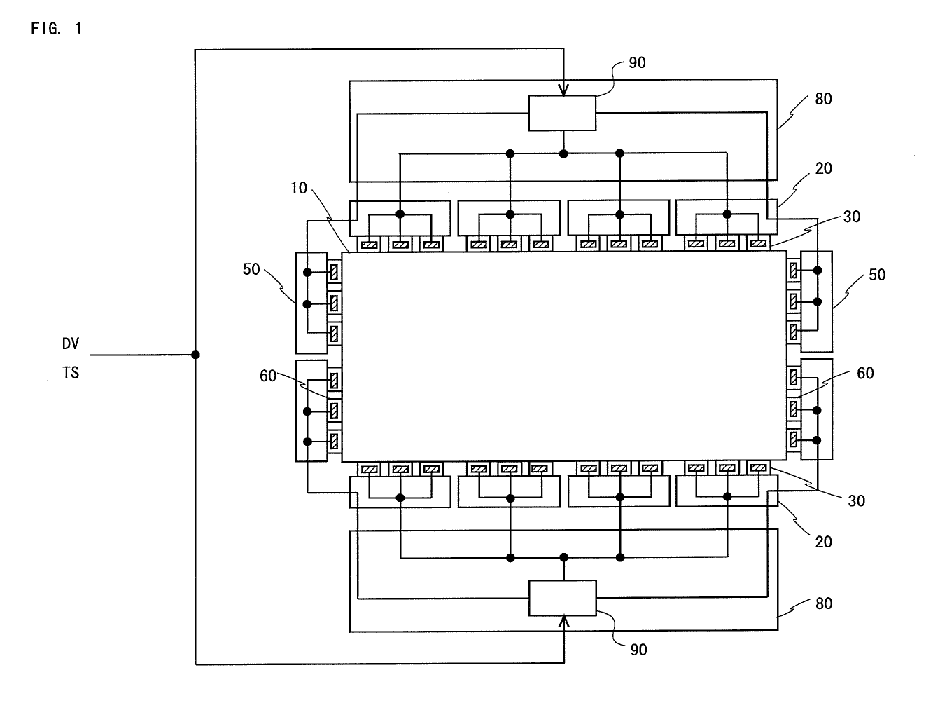

FIG. 1 is a block diagram illustrating the configuration of a liquid crystal display device according to a first embodiment of the present invention. As shown in FIG. 1, the liquid crystal display device includes a liquid crystal panel 10 (also referred to as a “display panel”), control boards 80, source boards 20, SOF packages 30 pressure-bonded to the liquid crystal panel 10 and the source boards 20, gate boards 50, and SOF packages 60 pressure-bonded to the liquid crystal panel 10 and the gate boards 50. The SOF packages 30 are pressure-bonded along top and bottom edges of the liquid crystal panel 10 and are also divided into groups of a few to several, each group being pressure-bonded to one source board 20. The SOF package 30 is a flexible board in which a source driver (also referred to as a “data signal line driver circuit”) and other components are mounted on a flexible film substrate. Moreover, the SOF packages 60 are pressure-bonded along right and left edges of the liquid crystal panel 10 and are also divided into groups of a few to several, each group being pressure-bonded to one gate board 50. The SOF package 60 is also a flexible board in which a gate driver (also referred to as a “scanning signal line driver circuit”) and other components are mounted on a flexible film substrate. Note that the source boards 20 and the gate boards 50 will also be referred to collectively as the “circuit boards”.

Furthermore, disposed outside the source boards 20 are the control boards 80. The control boards 80 are provided with timing controllers 90 for generating required image data and control signals for driving the source drivers and the gate drivers, on the basis at least of externally provided image signals DV and timing signals TS. The image data and the control signals for controlling the source drivers are provided from the timing controllers 90 through the source boards 20 to source drivers (not shown) mounted in the SOF packages 30, whereas the control signals for controlling the gate drivers are provided from the timing controllers 90 sequentially through the source boards 20, the SOF packages 30, and the gate boards 50 to gate drivers (not shown) mounted in the SOF packages 60.

The number of SOF packages 30 and the number of SOF packages 60 are respectively determined by the number of data signal lines and the number of scanning signal lines, both of which are formed on the liquid crystal panel 10. Moreover, in FIG. 1, the SOF packages 30 are pressure-bonded along the top and bottom edges of the liquid crystal panel 10, and the SOF packages 60 are pressure-bonded along the right and left edges of the liquid crystal panel 10. However, the SOF packages 30 may be pressure-bonded along either the top or bottom edge of the liquid crystal panel 10, and the SOF packages 60 may be pressure-bonded along either the right or left edge of the liquid crystal panel 10.

The following is directed to the SOF package 30 in which to mount the source driver, and because the same description applies to the SOF package 60 in which to mount the gate driver, any description of the SOF package 60 will be omitted.

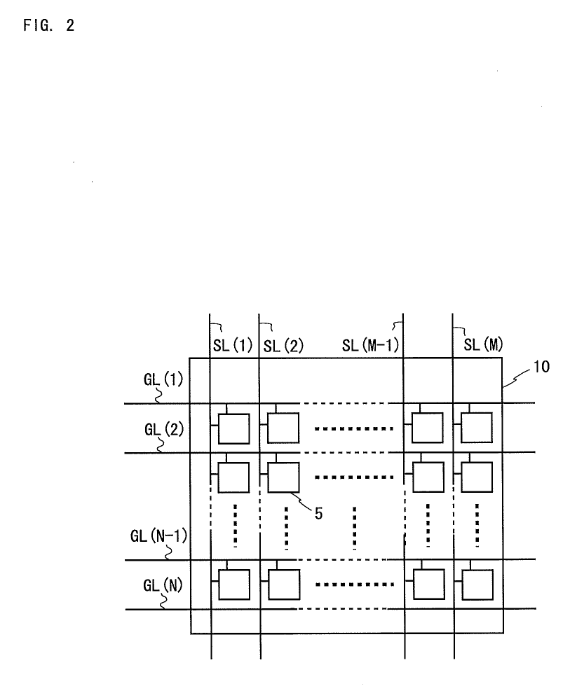

FIG. 2 is a diagram illustrating the arrangement of data signal lines and scanning signal lines formed on the liquid crystal panel 10 of the liquid crystal display device shown in FIG. 1. As shown in FIG. 2, the liquid crystal panel 10 has formed thereon a plurality (M) of parallel data signal lines SL(1) to SL(M) and a plurality (N) of parallel scanning signal lines GL(1) to GL(N), which cross each other.

Moreover, near the intersections of the data signal lines SL(1) to SL(M) and the scanning signal lines GL(1) to GL(N), there are formed pixel forming portions 5 for holding analog signal voltages provided by the source drivers via the data signal lines SL(1) to SL(M). The analog signal voltages generated by the source drivers are applied to the data signal lines SL(1) to SL(M), and the scanning signal lines GL(1) to GL(N) are selected one by one in a sequential manner on the basis of scanning signals generated by the gate drivers. The analog signal voltages being applied to the data signal lines are written to and held in the pixel forming portions 5 that are connected to the scanning signal line selected in the above manner, with the result that the liquid crystal display device displays an image on the liquid crystal panel 10. The data signal lines SL(1) to SL(M) are connected in groups of a predetermined number to the source drivers mounted in the SOF packages 30, and the scanning signal lines GL(1) to GL(N) are connected in groups of a predetermined number to the gate drivers mounted in the SOF packages 60.

<1.2 Configuration of the SOF Package>

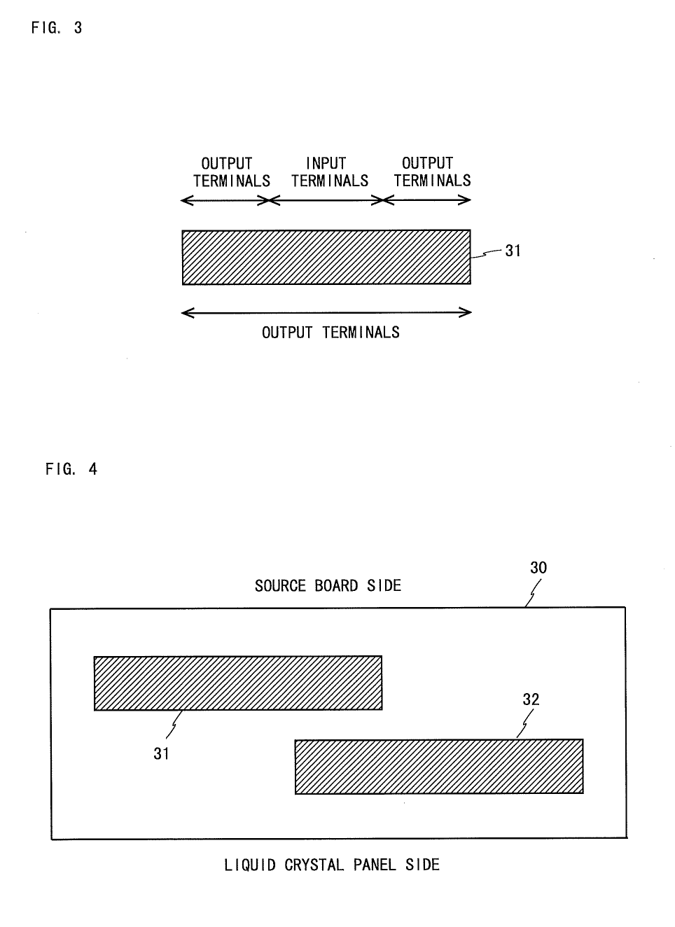

FIG. 3 is a diagram showing the arrangement of input terminals and output terminals of the source driver 31 used in the liquid crystal display device in FIG. 1. As shown in FIG. 3, the number of output terminals of the source driver 31 is considerably larger than the number of input terminals. Accordingly, the source driver 31 has some output terminals arranged along one long side, and the rest of the source drivers that cannot be arranged on that long side are arranged along the other long side together with the input terminals.

FIG. 4 is a plan view of the SOF package 30 used in the liquid crystal display device shown in FIG. 1 where two source drivers 31 and 32 are mounted. In the case where two source drivers 31 and 32 are mounted in one SOF package 30, given the layout of the wiring patterns connected to the output terminals, it is preferable to arrange the source drivers 31 and 32 on the flexible film substrate so as to be parallel to each other at a predetermined distance but displace the source drivers 31 and 32 from each other in the longitudinal direction so as to overlap each other only partially.

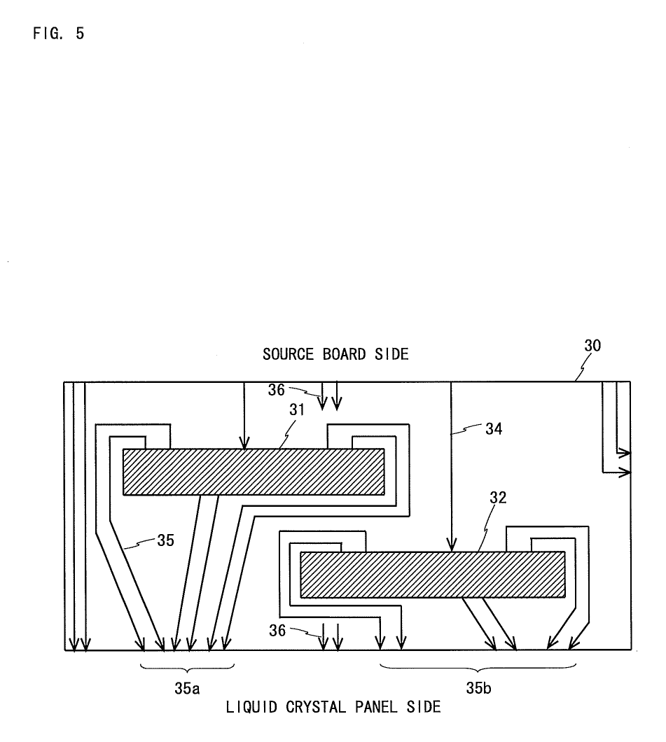

FIG. 5 is a diagram illustrating the layout of input wiring patterns 34 and output wiring patterns 35 for the source drivers 31 and 32 where the two source drivers are mounted in the SOF package 30. For each of the source drivers 31 and 32, the output wiring patterns 35 that are connected to the output terminals arranged along the long side of the source driver on the liquid crystal panel 10 side are formed so as to extend to the edge of the SOF package 30 on the liquid crystal panel 10 side, as shown in FIG. 5. However, the output wiring patterns 35 that are connected to the output terminals arranged along the long side of the source driver 31 on the source board 20 side are formed so as to extend to the edge of the SOF package 30 on the liquid crystal panel 10 through a spared space to the left of the source driver 31. Moreover, the output wiring patterns 35 that are connected to the right-side output terminals of the source driver 31 are formed so as to extend to the edge of the SOF package 30 on the liquid crystal panel 10 side through a spared space to the right of the source driver 31 as well as a spared space between the source driver 31 and the source driver 32. Note that the wiring patterns 35 that are connected to the output terminals of the source driver 31 will also be referred to collectively as the “first output wiring pattern group 35a”.

Likewise, the output wiring patterns 35 that are connected to the output terminals arranged along the long side of the source driver 31 on the liquid crystal panel 10 side are formed so as to extend to the edge of the SOF package 30 on the liquid crystal panel 10. The output wiring patterns 35 that are connected to the left-side output terminals of the source driver 32, which are arranged on the long side of the source driver 32 on the source board 20 side, are formed so as to extend to the edge of the SOF package 30 on the liquid crystal panel 10 through the space between the source driver 31 and the source driver 32 as well as a spared space to the right of the source driver 32. The output wiring patterns 35 that are connected to the right-side output terminals of the source driver 32 are formed so as to extend to the edge of the SOF package 30 on the liquid crystal panel 10 through a spared space to the right of the source driver 32. Note that the wiring patterns 35 that are connected to the output terminals of the source driver 32 will also be referred to collectively as the “second output wiring pattern group 35b”.

Furthermore, there are also formed wiring patterns for supplying the liquid crystal panel 10 with voltages provided by the control board 80, including a common voltage applied to a common electrode (not shown), which creates liquid crystal capacitance together with pixel electrodes (not shown), and auxiliary capacitance voltages applied to auxiliary capacitance lines (not shown), which create auxiliary capacitance. These voltages are directly provided to the liquid crystal panel 10, and therefore, directly provided to the liquid crystal panel 10 via the wiring patterns provided near either the right or left edge of the SOF package 30. Moreover, the gate driver control signals generated by the timing controllers 90 are provided to the gate boards 50 through the SOF packages 30, and therefore, the wiring patterns therefor are also formed near the edges of the SOF packages 30. Further, the SOF packages 30 have formed therein dummy wiring patterns 36 respectively connected to dummy connection terminals 18 of the liquid crystal panel 10 and dummy connection terminals 28 of the source boards 20, both of which will be described later. Accordingly, neither signals nor voltages are applied to the dummy wiring patterns 36.

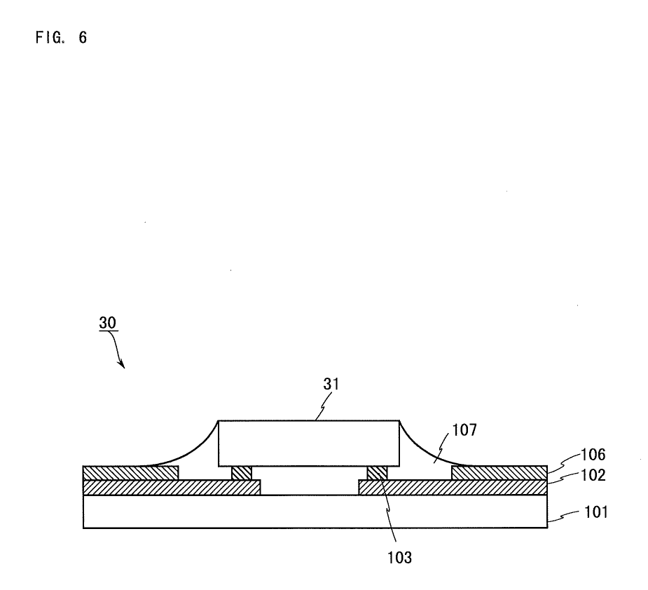

FIG. 6 is a diagram illustrating in cross section the SOF package 30 with the source driver 31 mounted therein. As shown in FIG. 6, wiring conductors 102 are formed with a copper (Cu) tin film on the film substrate 101. The source driver 31 is electrically connected to the wiring conductors 102 via gold (Au) bumps 103 formed on the wiring conductors 102. Moreover, the wiring conductors 102 are covered with a solder resist 106, and the connections between the source driver 31 and the wiring conductors 102 are protected by a filler 107. In this manner, the SOF package 30 with the source driver 31 mounted therein is formed. As can be seen, all inner leads of the SOF package are tightly fixed to the film substrate, and therefore, are not deformed, which makes it possible to achieve a fine lead pitch.

<1.3 Arrangement of Connection Terminals on the Liquid Crystal Panel and the Source Board>

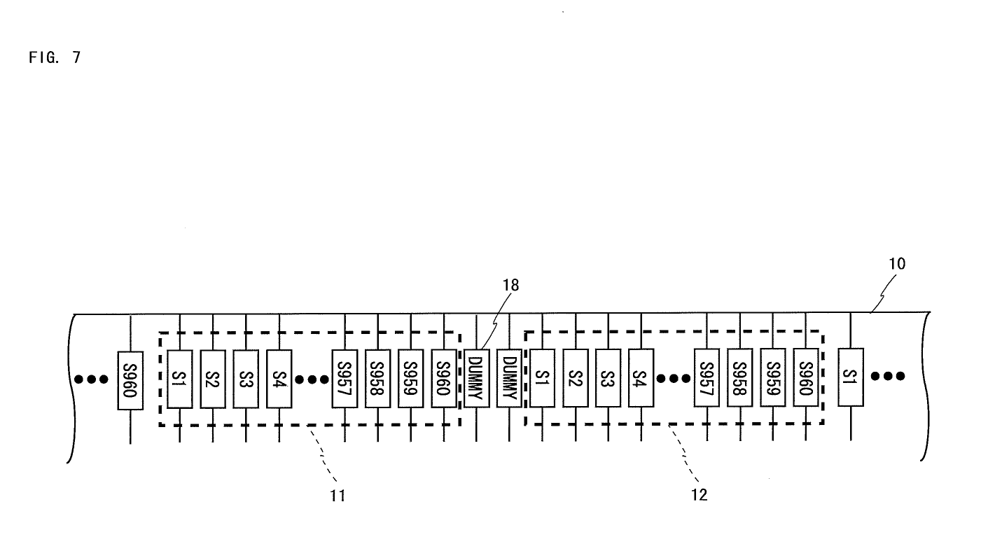

FIG. 7 is a diagram showing a part of the arrangement of connection terminals which are formed on the liquid crystal panel 10 and to which the output wiring patterns of the SOF package 30 are to be pressure-bonded. Both of the source drivers 31 and 32 pressure-bonded to the liquid crystal panel 10 support 960 channels. As shown in FIG. 7, the liquid crystal panel 10 includes a first connection terminal group 11, which consists of 960 connection terminals S₁ to S₉₆₀, a second connection terminal group 12, which consists of 960 connection terminals S₁ to S₉₆₀, and two dummy connection terminals 18 arranged between and aligned with the groups. Moreover, although not shown in the figure, the liquid crystal panel 10 includes a plurality of connection terminal groups, each group consisting of a set of a first connection terminal group 11, a second connection terminal group 12, and two dummy connection terminals 18 provided therebetween, as above, and these connection terminal groups of the same components are arranged in a line along the edge of the liquid crystal panel 10.

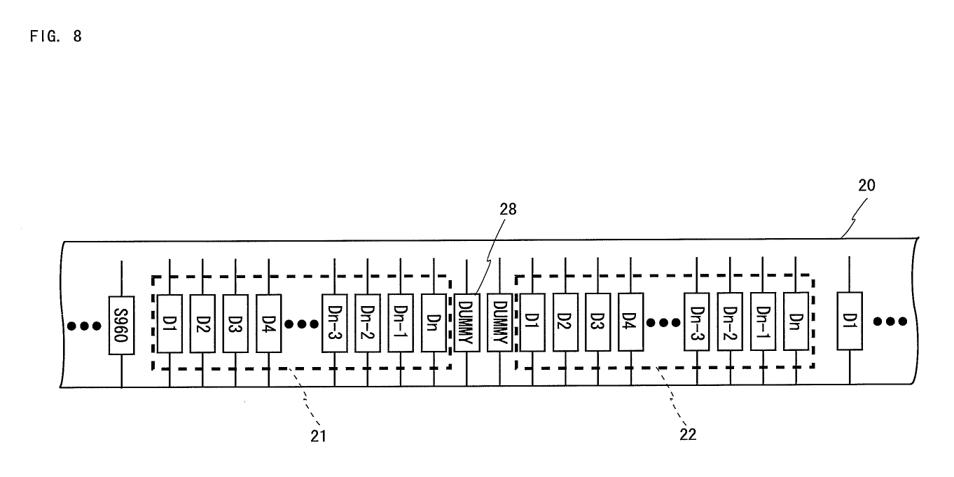

FIG. 8 is a diagram showing a part of the arrangement of connection terminals which are formed on the source board 20 and to which the input wiring patterns of the SOF package 30 are to be pressure-bonded. As with the liquid crystal panel 10, the source board 20 includes a first connection terminal group 21, which consists of n connection terminals D₁ to Dₙ, a second connection terminal group 22, which consists of n connection terminals D₁ to Dₙ, and two dummy connection terminals 28 arranged between and aligned with the groups. Moreover, although not shown in the figure, the source board 20 includes a plurality of connection terminal groups, each group consisting of a set of a first connection terminal group 21, a second connection terminal group 22, and two dummy connection terminals 28 provided therebetween, as above, and these connection terminal groups of the same components are arranged in a line along the edge of the source board 20.

<1.4 Pressure-bonding of the Liquid Crystal Panel and the Source Board to the SOF Package>

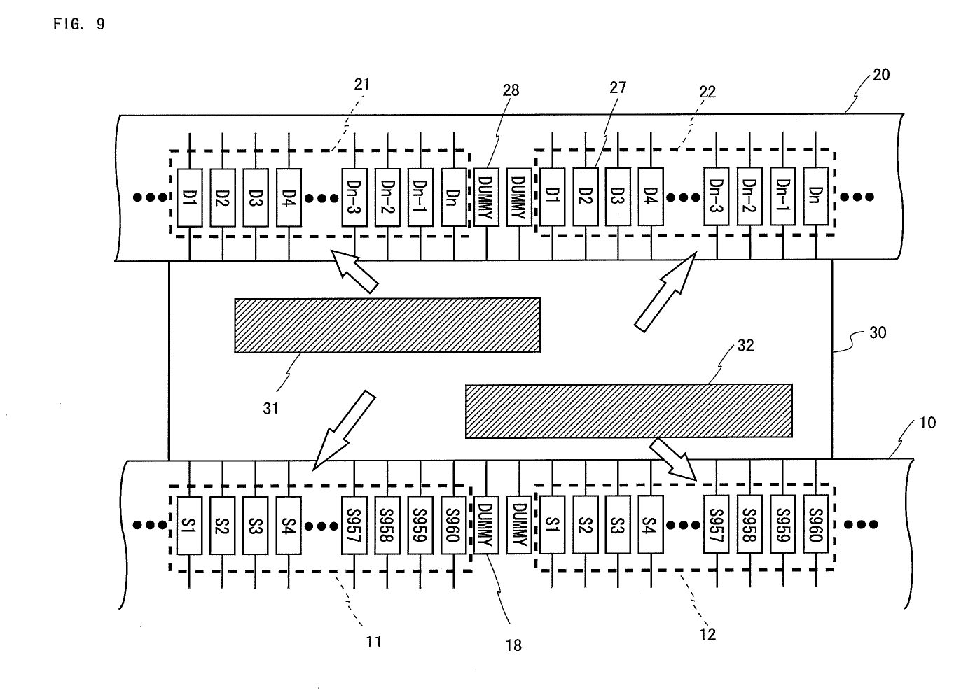

FIG. 9 is a diagram illustrating the state where the output wiring patterns and the input wiring patterns of the SOF package 30 are respectively pressure-bonded to the connection terminals of the liquid crystal panel 10 and the connection terminals of the source board 20. As shown in FIG. 9, the connection terminals S₁ to S₉₆₀ in the first connection terminal group 11 of the liquid crystal panel 10 are connected to the output wiring patterns of the source driver 31, and the connection terminals S₁ to S₉₆₀ in the second connection terminal group 12 are connected to the output wiring patterns of the source driver 32.

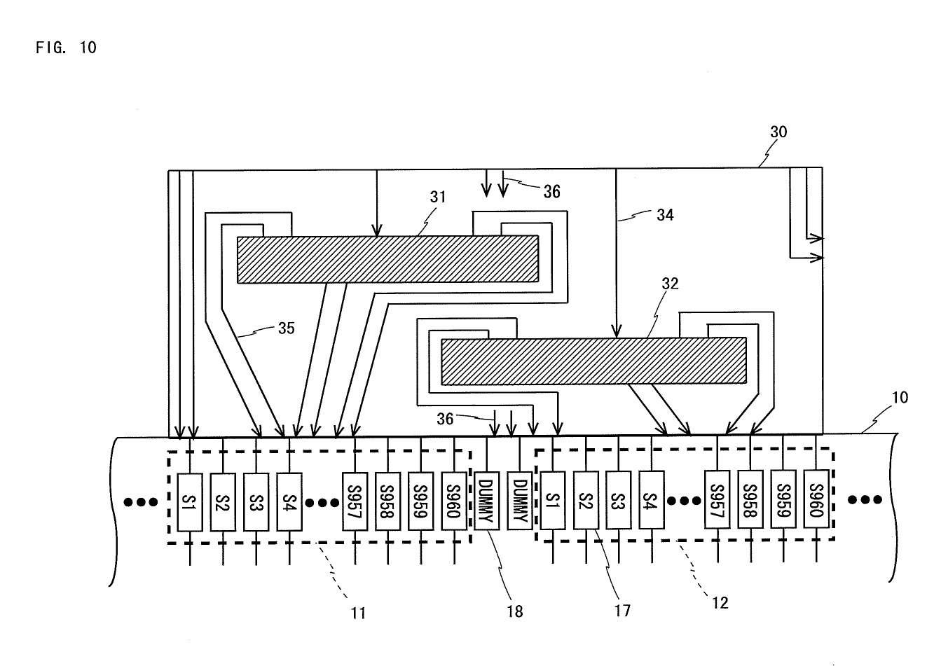

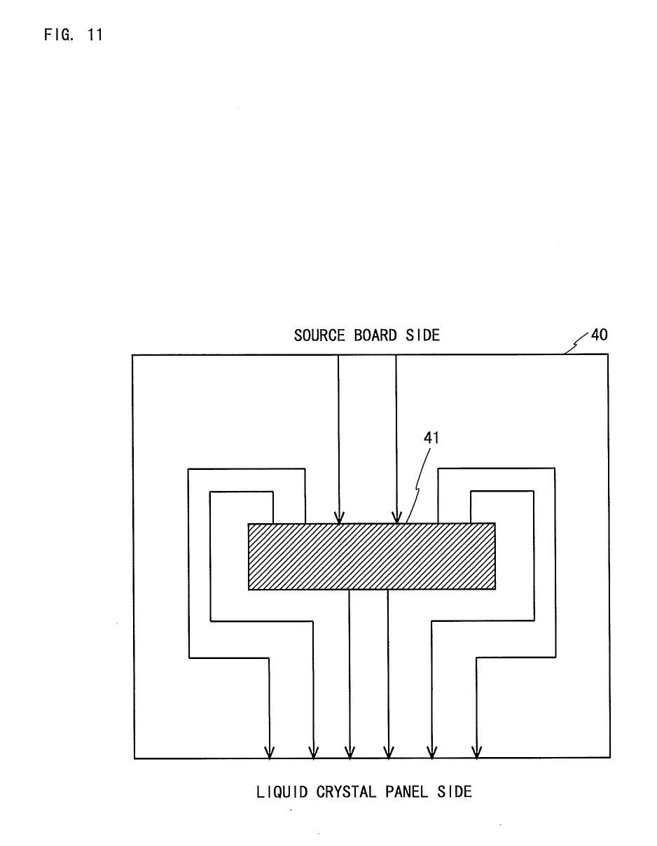

A detailed description will be given below concerning the state of the connections between the output wiring patterns of the SOF package 30 and the connection terminals of the liquid crystal panel 10. FIG. 10 is a diagram illustrating the connection of the output wiring patterns 35 and the dummy wiring patterns 36 formed on the SOF package 30 to the connection terminals of the liquid crystal panel 10. As shown in FIG. 10, of the two source drivers 31 and 32 mounted in the SOF package 30, the source driver 31 has the output wiring patterns (the wiring patterns in the first output wiring pattern group) pressure-bonded to the connection terminals S₁ to S₉₆₀ included in the first connection terminal group 11 of the liquid crystal panel 10. The source driver 32 has the output wiring patterns (the wiring patterns in the second output wiring pattern group) pressure-bonded to the connection terminals S₁ to S₉₆₀ included in the second connection terminal group 12 of the liquid crystal panel 10. The dummy wiring patterns 36 are respectively pressure-bonded to the two dummy connection terminals 18 formed in the space between the first connection terminal group 11 and the second connection terminal group of the liquid crystal panel 10. Further, the common voltage and the auxiliary capacitance voltage are applied to wiring patterns formed near the left edge of the SOF package 30, and the gate driver control signals are provided to wiring patterns formed near the right edge of the SOF package 30.

Referring back to FIG. 9, the n input wiring patterns 34 of the source driver 31 are respectively connected to the connection terminals D₁ to Dₙ in the first connection terminal group 21 of the source board 20, and the n input wiring patterns 34 of the source driver 32 are respectively connected to the connection terminals D₁ to Dₙ in the second connection terminal group 22 of the source board 20. Moreover, the two dummy wiring patterns 36 formed on the SOF package 30 are respectively connected to the two dummy connection terminals 28. Note that unlike the output wiring patterns, the input wiring patterns 34 for providing input signals from the source board 20 to the source drivers 31 and 32 are not laid out in a complex manner, and therefore, any detailed description thereof will be omitted.

In the case where a plurality of SOF packages 30 are pressure-bonded to the liquid crystal panel 10, also, the output wiring patterns and the dummy wiring patterns of each of the SOF packages 30 are respectively pressure-bonded to the connection terminals and the dummy connection terminals of the liquid crystal panel 10, and the input wiring patterns and the dummy wiring patterns of the SOF package 30 are respectively pressure-bonded to the connection terminals and the dummy connection terminals of the source board 20. As a result, the SOF packages 30 can be pressure-bonded to the liquid crystal panel 10 and also to the source board 20.

The following is the reason why the dummy wiring patterns 36 and the dummy connection terminals 18 are respectively provided to the SOF package 30 and the liquid crystal panel 10 and pressure-bonded together as described above. If the source driver is further miniaturized, with the result that wiring patterns can be formed around the source driver mounted in an SOF package, such an SOF package with a single source driver mounted therein is used in place of the SOF package 30. In such a case, if there is no spared space between the first connection terminal group 11 and the second connection terminal group 12 arranged on the liquid crystal panel 10, two SOF packages are pressure-bonded with their edges overlapping each other. Therefore, to prevent the two SOF packages from overlapping each other, the liquid crystal panel 10 is required to be redesigned to change the position of the connection terminals. To avoid such a design change, some space is spared between the first connection terminal group 11 and the second connection terminal group 12.

In the case where an SOF package 30 with two source drivers mounted therein is pressure-bonded to the liquid crystal panel 10 with a spared space, if the SOF package to be pressure-bonded to the liquid crystal panel 10 has a space spared simply at a position corresponding to the spared space on the liquid crystal panel 10, the SOF package tends to loosen from the liquid crystal panel 10 at the position of the spared space. In such a state, if the liquid crystal panel 10 is heated, the SOF package might expand due to the heat. At this time, the amount of heat expansion varies between the portions pressure-bonded to the connection terminals of the SOF package and the loose portion not being firmly pressure-bonded to the connection terminals. As a result, a load is applied to the closest connection terminal to the loose portion without being firmly pressure-bonded, with the result that connection defects such as peeling off might occur at the closest connection terminal. Note that the dummy wiring patterns 36 provided on the SOF package 30 will also be referred to as the “first looseness prevention portion”, and the dummy connection terminals 18 provided to the liquid crystal panel 10 and the dummy connection terminals 28 provided to the source board will also be referred to as the “second connection terminals”.

Therefore, to preclude the SOF package from loosening in a spared space on the liquid crystal panel 10, the SOF package 30 is provided with the dummy wiring patterns, which are pressure-bonded to the dummy connection terminals 18 provided to the liquid crystal panel 10. As a result, the SOF package 30 is fixed to the liquid crystal panel 10 even in a spared space, with the result that the SOF package 30 does not loosen from the liquid crystal panel in any portion. Thus, the occurrence of connection defects can be prevented.

<1.5 Effects>

FIG. 11 is a diagram illustrating an SOF package 40 with a miniaturized source driver 41 mounted therein. As shown in FIG. 11, the SOF package with only one miniaturized source driver mounted therein can spare spaces to the left and the right of the source driver. Thus, the output wiring patterns connected to the output terminals on the source board 20 side can be formed so as to extend through these spared spaces to the edge on the liquid crystal panel 10 side.

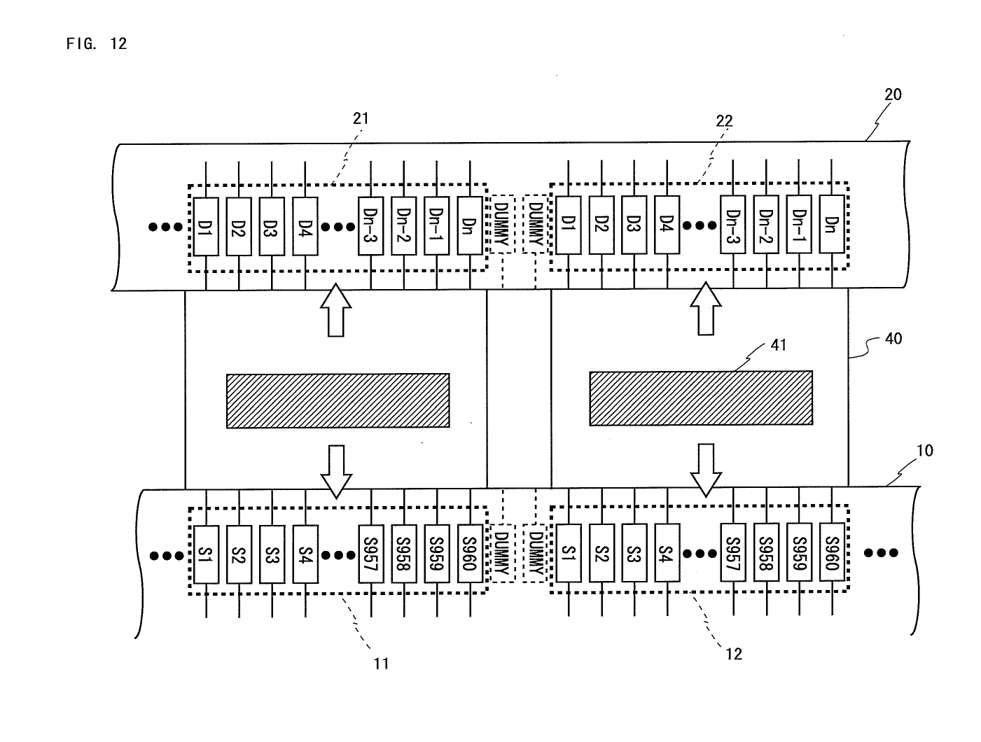

FIG. 12 is a diagram illustrating the state where SOF packages 40, as shown in FIG. 11, are pressure-bonded to the liquid crystal panel 10 and the source board 20. As shown in FIG. 12, the output wiring patterns of the two SOF packages 40 can be respectively pressure-bonded to the connection terminals included in the first connection terminal group 11 and the second connection terminal group of the liquid crystal panel 10 without changing the arrangement of the connection terminals of the first and second connection terminal groups 11 and 12. Likewise, the input wiring patterns of the two SOF packages 40 can be respectively pressure-bonded to the connection terminals included in the first connection terminal group 21 and the second connection terminal group 22 of the source board 20 without changing the arrangement of the connection terminals of the first and second connection terminal groups 21 and 22. In this manner, in the case where the SOF package 40 is used, the same liquid crystal panel 10 and source board 20 as those used with the SOF package 30 can still be used. Thus, the production cost of the liquid crystal display device can be reduced.

Furthermore, the SOF package 30 is provided with the dummy wiring patterns 36, and the liquid crystal panel and the source board 20 are provided with the dummy connection terminals 18 and 28, with the result that the SOF package 30 can be precluded from loosening from the liquid crystal panel 10 and the source board 20. Thus, it is possible to prevent the occurrence of connection defects at the portions where the SOF package 30 is pressure-bonded to the liquid crystal panel 10 and the source board 20.

Furthermore, one SOF package 30 is replaced by two SOF packages 40, eliminating the need for the dummy connection terminals 18 and 28 respectively provided to the liquid crystal panel 10 and the source board 20. Thus, the spaces for forming the dummy connection terminals 18 and 28 can be utilized as new wiring spaces, resulting in an increased degree of freedom in designing the wiring patterns formed on the liquid crystal panel 10 and the source board 20.

It should be noted that even if miniaturization of the source driver for the liquid crystal display device is feasible, the SOF package 30 can continue to be used instead of using the SOF package 40, considering production cost, reliability, workability for production process, etc. Moreover, either the SOF package 30 or the SOF package 40 may be selectively used depending on the purpose or other factors. In either case, the liquid crystal panel 10 and the source board 20 can be used without modification, and therefore, it is simply required to change the SOF packages.

<1.6 Variants>

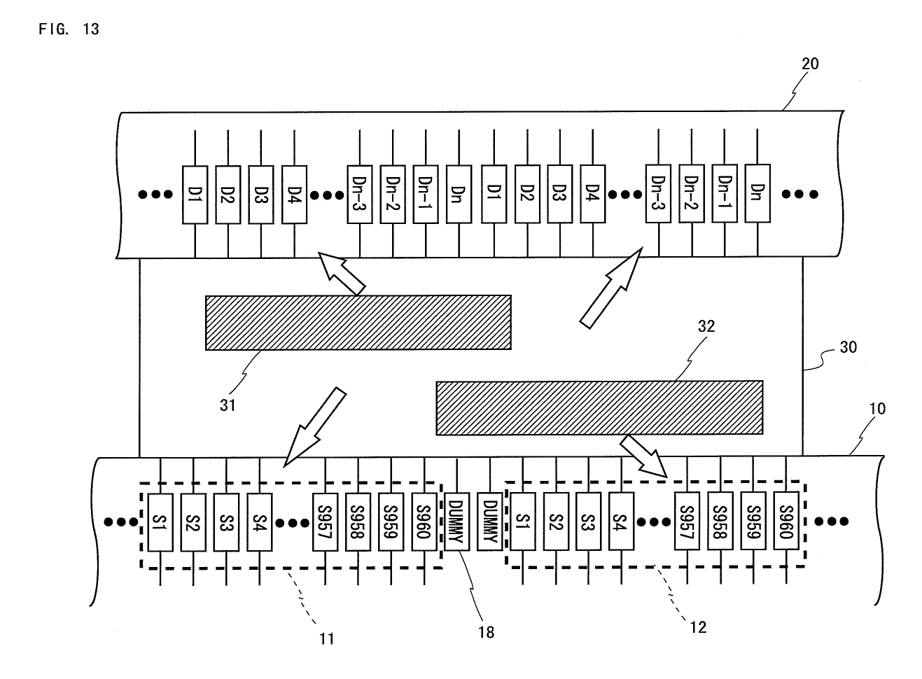

In the embodiment, when the SOF package 30 with two source drivers 31 and 32 mounted therein is pressure-bonded to the liquid crystal panel, the dummy connection terminals 18 are provided between the first connection terminal group 11 and the second connection terminal group 12 of the liquid crystal panel 10, and also the dummy connection terminals 28 are provided between the first connection terminal group 21 and the second connection terminal group 22 of the source board 20. However, these dummy connection terminals may be provided to only one of the liquid crystal panel 10 or the source board 20. FIG. 13 is a diagram illustrating a liquid crystal display device according to a variant of the present embodiment where only the liquid crystal panel 10 is provided with dummy connection terminals 18, and the SOF package 30 is pressure-bonded to the liquid crystal panel 10 and the source board 20. As shown in FIG. 13, the two dummy connection terminals 18 are provided between the first connection terminal group 11 and the second connection terminal group 12 of the liquid crystal panel, whereas there are no dummy connection terminals provided between the first connection terminal group 21 and the second connection terminal group 22 of the source board 20.

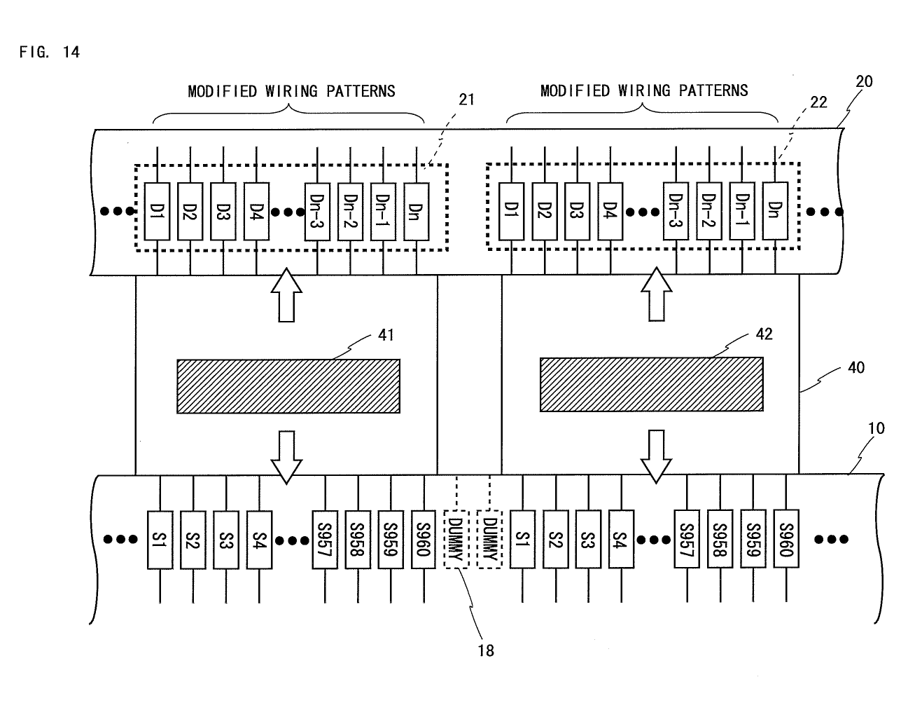

This state will be described with respect to a case where SOF packages 40 are used, each having only one source driver 41 mounted therein because of advances in source driver miniaturization. FIG. 14 is a diagram illustrating the liquid crystal display device shown in FIG. 13 where two SOF packages 40, each having one source driver mounted therein, rather than the SOF package 30, are pressure-bonded to the liquid crystal panel 10 and the source board 20. As shown in FIG. 14, the liquid crystal panel 10 is provided with the dummy connection terminals, and therefore, the first connection terminal group 11 and the second connection terminal group 12 are distanced to a certain degree or more. Thus, even when the two SOF packages 40 are used in place of the SOF package 30, it is not necessary to design a new liquid crystal panel with a changed connection terminal arrangement, and the same liquid crystal panel 10 as that used with the SOF package 30 can be used.

However, the source board 20 is provided with no dummy connection terminals. Therefore, when the two SOF packages 40, rather than the SOF package 30, are pressure-bonded, the input wiring patterns of the SOF package 40 connected to the source driver 31 do not positionally correspond to the connection terminals in the first connection terminal group 21 of the source board 20. Likewise, the input wiring patterns of the SOF package 40 connected to the source driver 32 do not positionally correspond to the connection terminals in the second connection terminal group 22 of the source board 20. Therefore, to change the position of the connection terminals, the source board 20 is required to be redesigned. As a result, it is necessary to produce a new source board, even though the same liquid crystal panel 10 as that used with the SOF package 30 can still be used.

It should be noted that in the case where only the source board 20 is provided with dummy connection terminals, and two SOF packages 40 are pressure-bonded in place of the SOF package 30, it is not necessary to redesign the source board. Accordingly, the same source board 20 as that used with the SOF package 30 can be used, but it is still necessary to redesign the liquid crystal panel. This is the same as in the case where the dummy connection terminals are provided to the liquid crystal panel 10, and therefore, any detailed description and figure will be omitted. In this manner, in the case where only one of the liquid crystal panel 10 or the source board 20 is desired to be used, only the desired one can be provided with dummy connection terminals, and also the SOF package 30 can be provided with dummy wiring patterns at a corresponding position.

### 2. Second Embodiment

Next, a liquid crystal display device according to a second embodiment of the present invention will be described. The block diagram of the liquid crystal display device according to the present embodiment and the diagram illustrating the liquid crystal panel 10 are the same as FIGS. 1 and 2, respectively, and therefore, such diagrams and any descriptions thereof will be omitted.

<2.1 Configuration of the SOF Package>

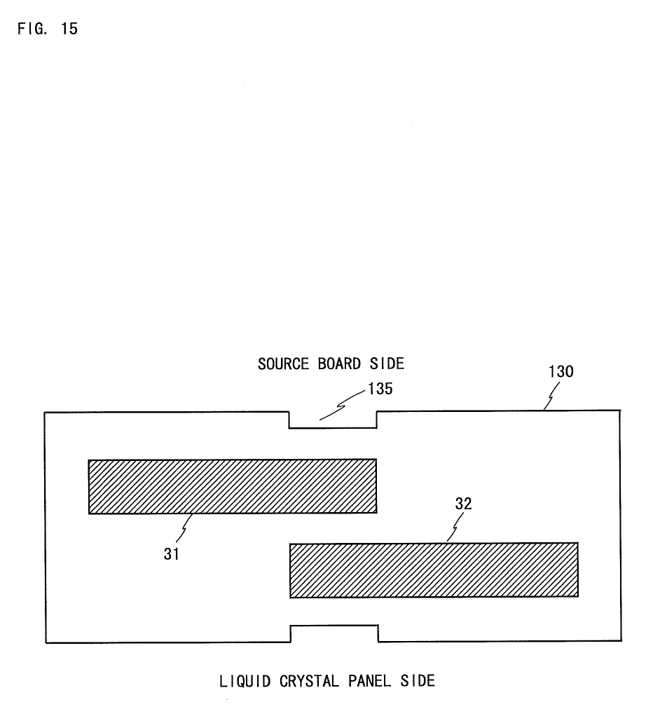

FIG. 15 is a plan view of an SOF package 130 used in the liquid crystal display device according to the present embodiment where two source drivers 31 and 32 are mounted in the package. As in the case of the SOF package 30 shown in FIG. 4, the SOF package 130 shown in FIG. 15 has the two source drivers 31 and 32 mounted on a flexible film substrate. The two source drivers 31 and 32 are arranged in the same manner as in FIG. 4, the layout of wiring patterns for the SOF package 130 is the same as in FIG. 5, and therefore, any descriptions thereof will be omitted.

However, unlike the SOF package 30, the SOF package 130 has cuts 135 provided at the center of each side parallel to the long sides of the source drivers 31 and 32. The cuts 135 are formed so as to be positioned between the first connection terminal group 11 and the second connection terminal group 12 provided to the liquid crystal panel 10 when the SOF package 130 is pressure-bonded to the liquid crystal panel 10, and the length of each cut 135 is approximately equal to the distance between the first connection terminal group 11 and the second connection terminal group 12. Moreover, as for the dimension (depth) vertical to the longitudinal direction, the cuts 135 are formed to such a depth that the cuts 135 do not overlap the liquid crystal panel 10 when the SOF package 130 is pressure-bonded to the liquid crystal panel 10.

<2.2 Pressure-bonding of the Liquid Crystal Panel and the Source Board to the SOF Package>

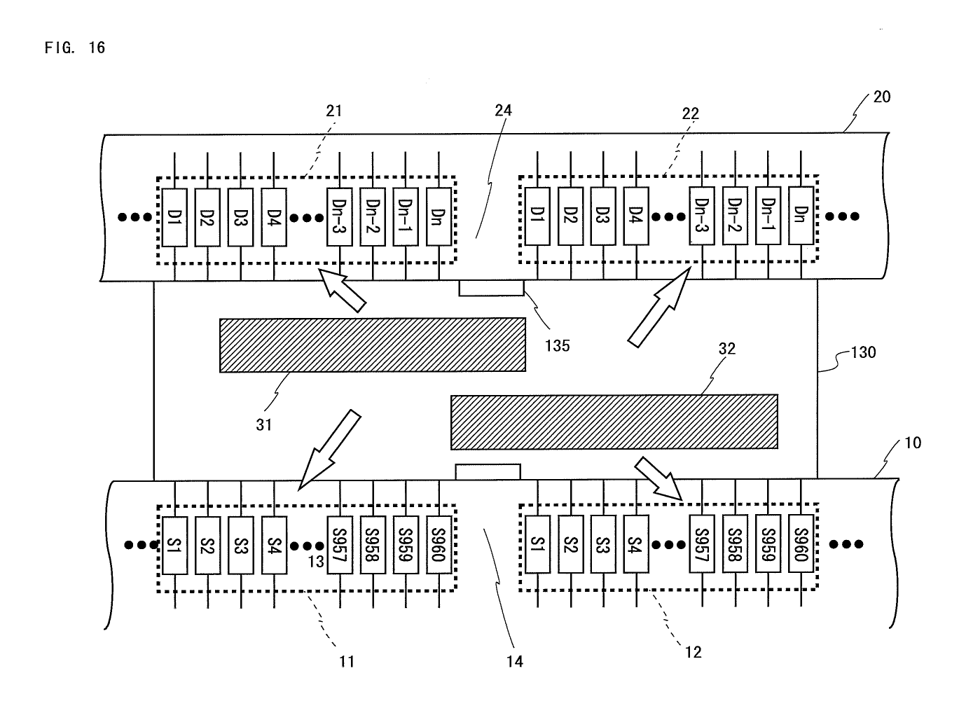

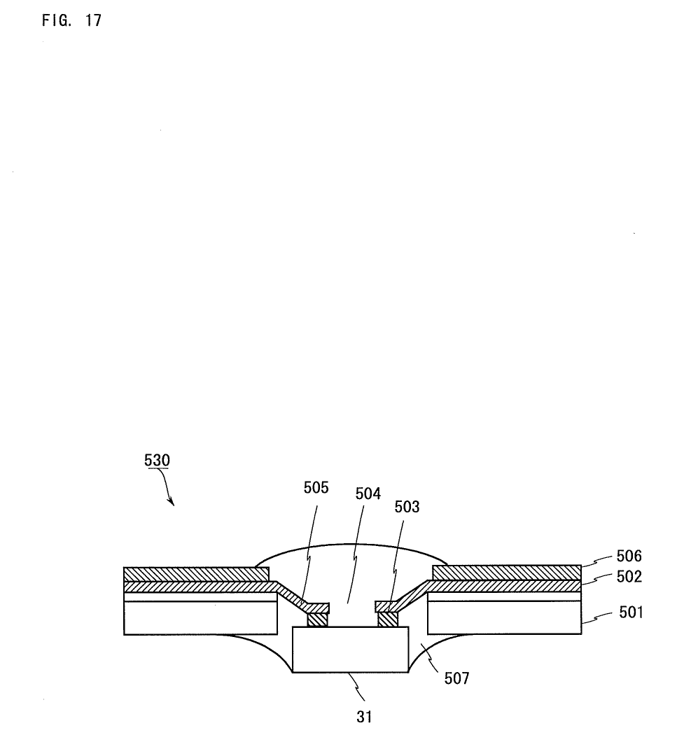

FIG. 16 is a diagram illustrating the state where the output wiring patterns and the input wiring patterns of the SOF package 130 are respectively pressure-bonded to the liquid crystal panel 10 and the source board 20. As shown in FIG. 16, connected to the connection terminals S₁ to S₉₆₀ in the first connection terminal group 11 of the liquid crystal panel 10 are respectively the 960 output wiring patterns of the source driver 31 mounted in the SOF package 130, and connected to the connection terminals S₁ to S₉₆₀ in the second connection terminal group 12 are respectively the 960 output wiring patterns of the source driver 32. Moreover, there is a spared space 14 between the first connection terminal group 11 and the second connection terminal group 12. When the output wiring patterns of the SOF package 130 are respectively pressure-bonded to the connection terminals of the liquid crystal panel 10, one of the cuts 135 formed in the SOF package 130 is disposed at a position corresponding to the space 14. Similarly, when the input wiring patterns of the SOF package 130 are respectively pressure-bonded to the connection terminals in the first connection terminal group 21 and the second connection terminal group 22 of the source board 20, the other of the cuts 135 formed in the SOF package 130 is disposed at a position corresponding to a spared space 24. Note that the wiring patterns 35 that are connected to the output terminals of the source driver 31 will also be referred to collectively as the “first output wiring pattern group 35a”, and the wiring patterns 35 that are connected to the output terminals of the source driver 32 will also be referred to collectively as the “second output wiring pattern group 35b”. Moreover, the cuts 135 will also be referred to as the “first looseness prevention portions”, and the spared space 14 on the liquid crystal panel 10 and the spared space 24 on the source board 20 will also be referred to collectively as the “second looseness prevention portions”.

It should be noted that the connections between the output wiring patterns formed on the SOF package 130 and the first and second connection terminal groups 11 and 12 of the liquid crystal panel 10 are the same as those shown in FIG. 10, and therefore, any descriptions thereof will be omitted.

The following is the reason why the cuts 135 are provided in the SOF package 130 as described above. In the case where an SOF package with no cuts 135 is pressure-bonded to the liquid crystal panel 10, some load is placed on the closest connection terminal to, if any, a portion of the SOF that is loose without being properly pressure-bonded, with the result that connection defects such as peeling off become more likely to occur at the closest connection terminal, as described in the first embodiment. However, in the case of the SOF package 130 with the cuts 135 provided at portions that are prone to loosen, these portions are resistant to loosening, making it possible to prevent the occurrence of connection defects between the wiring patterns of the SOF package 130 and the connection terminals of the liquid crystal panel 10. While the foregoing has been directed to the case where the SOF package 130 is pressure-bonded to the liquid crystal panel 10, the same applies to the case where the SOF package 130 is pressure-bonded to the source board 20, and the source board 20 is also provided with cuts 135.

<2.3 Effects>

In the present embodiment, in the case where the SOF package has only one miniaturized source driver 41 mounted therein, the SOF package is the same as the SOF package 40 shown in FIG. 11. The state of the SOF package 40 being pressure-bonded to the liquid crystal panel 10 and the source board 20 is the same as the state shown in FIG. 12. Accordingly, as in the case shown in FIG. 12, the output wiring patterns of two SOF packages 40 can be respectively pressure-bonded to the connection terminals included in the first connection terminal group 11 and the second connection terminal group 12 of the liquid crystal panel 10 without changing the position of the connection terminals in the first and second connection terminal groups 11 and 12. Likewise, the input wiring patterns of the two SOF packages can be respectively pressure-bonded to the connection terminals included in the first connection terminal group 21 and the second connection terminal group 22 of the source board 20 without changing the position of the connection terminals in the first and second connection terminal groups 21 and 22. In the case where such SOF packages 40 are used, it is not necessary to redesign the liquid crystal panel 10 and the source board 20 in order to change the arrangement of the connection terminals, and the same liquid crystal panel 10 and source board 20 as those used with the SOF package 130 can still be used. Thus, the production cost of the liquid crystal display device can be reduced.

Furthermore, the SOF package 130 is provided with the cuts 135, and the liquid crystal panel 10 and the source board 20 are provided with the spared spaces 14 and 24, with the result that the SOF package 130 can be prevented from loosening from the liquid crystal panel 10 and the source board 20. Thus, it is possible to prevent the occurrence of connection defects at the portions where the SOF package 130 is pressure-bonded to the liquid crystal panel 10 and the source board 20.

Furthermore, the spared space 14, which is provided between the first and second connection terminal groups 11 and 12 of the liquid crystal panel 10, and the spared space 24, which is provided between the first and second connection terminal groups 21 and 22 of the source board 20, can be utilized as additional wiring spaces, resulting in an increased degree of freedom in designing the wiring patterns on the liquid crystal panel 10 and the source board 20.

It should be noted that even if miniaturization of the source driver for the liquid crystal display device is feasible, the SOF package 30 can continue to be used instead of using the SOF package 40, considering production cost, reliability, workability for production process, etc. Moreover, either the SOF package 30 or the SOF package 40 may be selectively used depending on the purpose or other factors. In either case, the liquid crystal panel 10 and the source board 20 can be used without modification, and therefore, it is simply required to change the SOF packages.

<2.4 Variant>

In the embodiment, in the case where the SOF package 130 with the two source drivers 31 and 32 mounted therein is pressure-bonded to the liquid crystal panel 10, the spared space 14 is provided between the first connection terminal group 11 and the second connection terminal group 12 of the liquid crystal panel 10, and further, the spared space 24 is provided between the first connection terminal group 21 and the second connection terminal group 22 of the source board 20. However, only one of the liquid crystal panel 10 or the source board 20 may be provided with such a spared space. For example, in the case where only the liquid crystal panel 10 is provided with the spared space 14, the spared space 14 is simply provided in place of the dummy connection terminals on the liquid crystal panel 10 in FIG. 13, and therefore, any figure and description will be omitted. The liquid crystal panel 10 provided with such a spared space can be used without a design change, even when the SOF packages 40 are pressure-bonded in place of the SOF package 130. The same applies to the case where only the source board 20 is provided with the spared space 24. In this manner, when only one of the liquid crystal panel 10 or the source board is desired to be used, only the desired one can be provided with a spared space, and the SOF package 130 can be provided with the cut 135 at a corresponding position.

### 3. Variants Common to the Embodiments

In the embodiments, the SOF package 30 or 130 with the source driver 31 or 32 mounted therein is pressure-bonded to the liquid crystal panel 10 and the source board 20. However, a TCP (tape carrier package) 530 with a source driver provided therein may be pressure-bonded to the liquid crystal panel 10 and the source board 20. FIG. 17 is a diagram illustrating in cross section the TCP 530 with the source driver 31 provided therein. As shown in FIG. 17, a film substrate 501 is provided with a device hole 504, and attached to the film substrate 501 are wiring conductors 502 made with a copper thin film and extending inside the device hole 504 at leading ends to serve as flying leads. The source driver 31 is electrically connected to the source driver 31 via gold bumps 503 formed at the leading ends of the wiring conductors 502. Furthermore, the wiring conductors 502 are covered in part with a solder resist 506, and the connections between the source driver 31 and the wiring conductors 502 are protected by a resin 507. In this manner, the TCP 530 is formed with the source driver 31 provided therein.

The TCP 530 has the wiring conductors 502 inside the device hole 504, and therefore, also due to the thickness of the copper thin film, it is more difficult to achieve a fine lead pitch for the TCP 530 than for the SOF package 30, but still, the TCP 530 can be used in place of the SOF package 30. Moreover, a TCP with cuts 135 provided in opposite side surfaces can be used in place of the SOF package 130. Accordingly, the SOF packages 30 and 130 and the TCP 530 will also be referred to herein collectively as the “component-mounting flexible boards”.

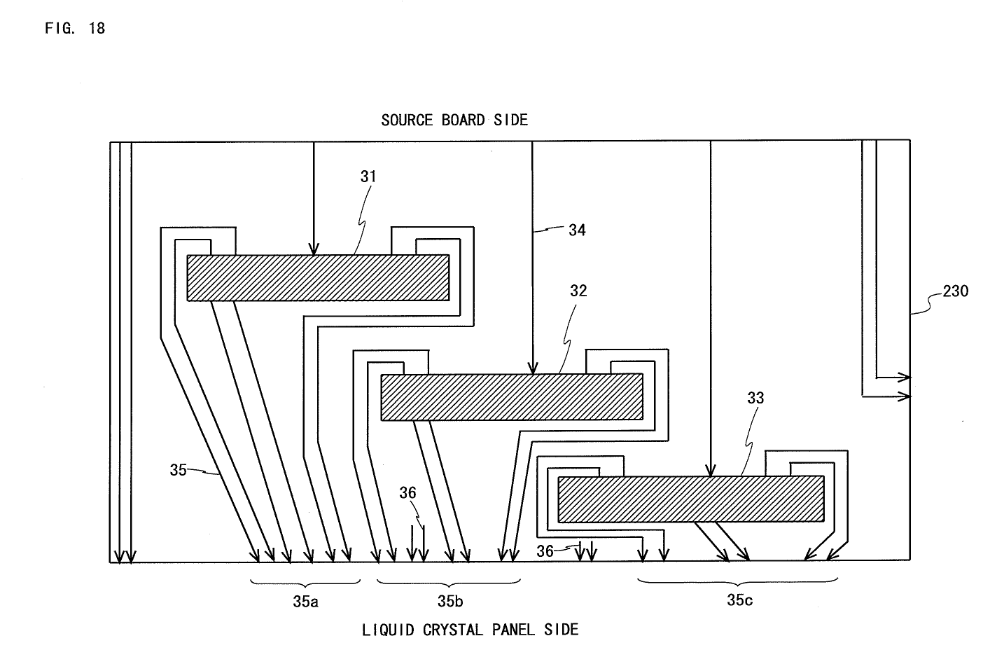

Furthermore, the embodiments have been described with respect to the case where the SOF package 30 or 130 with two source drivers mounted therein is used, but an SOF package 230 with three or more source drivers mounted therein may be used. FIG. 18 is a plan view illustrating the SOF package 230 with three source drivers 31 to 33 mounted therein. As shown in the figure, the three source drivers 31 to 33 are mounted at predetermined intervals so as to be parallel to one another along the longitudinal direction but displaced from one another in the longitudinal direction. Moreover, output wiring patterns that are connected to terminals of the source driver 31 on the source board 20 side are formed so as to extend to the edge on the liquid crystal panel 10 side through a spared space lateral to the short side of the source driver 31 or a spared space between the source driver 31 and the source driver 32. Output wiring patterns that are connected to terminals of the source driver 32 on the source board 20 side are formed so as to extend to the edge on the liquid crystal panel 10 side through the spared space between the source driver 31 and the source driver 32 or a spared space between the source driver 32 and the source driver 33. Output wiring patterns that are connected to terminals of the source driver 33 on the source board 20 side are formed so as to extend to the edge on the liquid crystal panel 10 side through a spared space lateral to the short side of the source driver 33 or the spared space between the source driver 32 and the source driver 33. These output wiring patterns are connected to connection terminals in a first, second, or third connection terminal group arranged on the liquid crystal panel 10. Note that the wiring patterns 35 connected to the output terminals of the source driver 31 will also be referred to collectively as the “first output wiring pattern group 35a”, the wiring patterns 35 connected to the output terminals of the source driver 32 will also be referred to collectively as the “second output wiring pattern group 35b”, and the wiring patterns 35 connected to the output terminals of the source driver 33 will also be referred to collectively as the “third output wiring pattern group 35c”.

Furthermore, the embodiments and the variants thereof have been described with respect to the SOF packages with the source drivers mounted therein. However, the present invention can be similarly applied to SOF packages with gate drivers mounted therein. Accordingly, the source driver and the gate driver are also referred to collectively as the “driver circuits”.

### INDUSTRIAL APPLICABILITY

The present invention is directed to component-mounting flexible boards and display devices, and is particularly suitable for component-mounting flexible boards on which to mount components required for driving display devices such as liquid crystal display devices, and also suitable for such display devices.

### DESCRIPTION OF THE REFERENCE CHARACTERS

10 liquid crystal panel (display panel)

11 first connection terminal group (output connection terminal group)

12 second connection terminal group (output connection terminal group)

14 spared space (second looseness prevention portion)

18, 28 dummy connection terminal (second looseness prevention portion)

20 source board (circuit board)

21 first connection terminal group (input connection terminal group)

22 second connection terminal group (input connection terminal group)

24 spared space (second looseness prevention portion)

30, 130 SOF package (component-mounting flexible board)

31, 32, 33 source driver

34 input wiring pattern

35 output wiring pattern

35a first output wiring pattern group

35b second output wiring pattern group

35c third output wiring pattern group

36 dummy wiring pattern (first looseness prevention portion)

40 SOF package (with miniaturized source driver mounted therein)

41 (miniaturized) source driver

50 gate board (circuit board)

60 SOF package (component-mounting flexible board)

135 cut (first looseness prevention portion)

1. A component-mounting flexible board for electrically connecting a display panel of a display device and a circuit board for supplying either image data or a control signal, or both, for driving the display panel, the component-mounting flexible board comprising:
a flexible film substrate;
a plurality of driver circuits configured to drive the display panel on the basis of either the image data or the control signal, or both, the driver circuits being mounted on the film substrate;
a plurality of input wiring patterns formed on the film substrate for each of the driver circuits so as to electrically connect input terminals of the driver circuit to the circuit board; and
a plurality' of output wiring patterns formed on the film substrate for each of the driver circuits so as to electrically connect output terminals of the driver circuit to the display panel, wherein,
the input wiring patterns constitute an input wiring pattern group for each of the driver circuits,
the output wiring patterns constitute an output wiring pattern group for each of the driver circuits, and
a first looseness prevention portion is formed either in a spared space between the input wiring pattern groups or a spared space between the output wiring pattern groups, or both,

2. The component-mounting flexible board according to claim 1, wherein the first looseness prevention portion consists of one or more dummy wiring patterns.

3. The component-mounting flexible board according to claim 1, wherein the first looseness prevention portion is a cut provided in the film substrate.

4. The component-mounting flexible board according to claim 1, wherein the component-mounting flexible board is an SOF package.

5. The component-mounting flexible board according to claim 1, wherein the component-mounting flexible board is a TCP.

6. The component-mounting flexible board according to claim 1, wherein both the input wiring pattern groups and the output wiring pattern groups are arranged such that the first looseness prevention portion formed in the spared space is interposed therebetween.

7. The component-mounting flexible board according to claim 1, wherein the driver circuit is a data signal line driver circuit configured to generate an analog signal voltage on the basis of the image data and apply the analog signal voltage to a data signal line formed on the display panel.

8. A display device comprising:
a display panel configured to display an image;
a component-mounting flexible board of claim 1 having mounted thereon a plurality of driver circuits configured to drive the display panel; and
a circuit board configured to supply image data and a control signal to the driver circuits, wherein,
the display panel includes for each of the driver circuits an output connection terminal group consisting of a plurality of connection terminals for connecting output wiring patterns of the component-mounting flexible hoard to the driver circuit,
the circuit board includes for each of the driver circuits an input connection terminal group consisting of a plurality of connection terminals for connecting input wiring patterns of the component-mounting flexible board to the driver circuit, and
either the output connection terminal groups of the display panel or the input connection terminal groups of the circuit board, or both, are arranged such that a second looseness prevention portion is disposed at a position corresponding to a first looseness prevention portion formed in or on the component-mounting flexible board.

9. The display device according to claim 8, wherein,
the first looseness prevention portion formed in or on the component-mounting flexible board consists of one or more dummy wiring patterns, and
the second looseness prevention portion formed on the display panel or the circuit board consists of one or more dummy connection terminals connectable to the dummy wiring pattern.

10. The display device according to claim 8, wherein,
the first looseness prevention portion formed in or on the component-mounting flexible board is a cut,
the second looseness prevention portion formed on the display panel or the circuit board is a spared space, and
the component-mounting flexible board is pressure-bonded to the display panel or the circuit board such that the cut overlaps neither the display panel nor the circuit board.
